(19) United States
(12) Patent Application Publication
(10) Pub. No.: US 2012/0168797 A1
(43) Pub. Date: Jul. 5, 2012

(54) LIGHT EMITTING DIODE CHIP AND METHOD FOR MANUFACTURING THE SAME

(75) Inventors: SHIH-CHENG HUANG, Hukou (TW); PO-MIN TU, Hukou (TW)

(73) Assignee: ADVANCED OPTOELECTRONIC TECHNOLOGY, INC., Hsinchu Hsien (TW)

(21) Appl. No.: 13/209,452

(22) Filed: Aug. 15, 2011

(30) Foreign Application Priority Data
Dec. 31, 2010 (CN) 201010618792.0

(51) Int. Cl. H01L 33/22

(52) U.S. Cl. 257/98; 438/29; 257/E33.074

(57) ABSTRACT

A method for manufacturing a light emitting diode chip, comprising steps: providing a substrate with a first patterned blocking layer formed thereon; growing a first n-type semiconductor layer on the substrate between the constituting parts of first patterned blocking layer, and stopping the growth of the first n-type semiconductor layer before the first n-type semiconductor layer completely covers the first patterned blocking layer; removing the first patterned blocking layer, whereby a plurality of first holes are formed at position where the first patterned blocking layer is originally existed; continuing the growth of the first n-type semiconductor layer until the first holes are completely covered by the first n-type semiconductor layer; and forming an active layer and a p-type current blocking layer on the first n-type semiconductor layer successively.

### BACKGROUND

1. Technical Field

The disclosure relates to light emitting diode chips, and particularly to a light emitting diode chip with high light extraction efficiency and a method for manufacturing such LED chip.

2. Description of the Related Art

Light emitting diodes' (LEDs) many advantages, such as high luminosity, low operational voltage, low power consumption, compatibility with integrated circuits, easy driving, long term reliability, and environmental friendliness have promoted their wide use as a lighting source.

Because optical paths of light from an active layer of a common light emitting diode chip are not perfect, light extraction and illumination efficiency of the common light emitting diode chip is limited; accordingly how to improve the light extraction efficiency of the light emitting diode chip is an industry priority.

Therefore, it is desirable to provide a light emitting diode chip with high light extraction efficiency and a method for manufacturing such an LED chip which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode chip with high light extraction efficiency. Moreover, in the drawings, like reference numerals designate corresponding parts throughout the views.

FIGS. 1-8 are cross sectional views of a vertical light emitting diode chip in different manufacturing steps of a method in accordance with a first embodiment of the present disclosure.

FIGS. 9-19 are cross sectional views of a vertical light emitting diode chip in different manufacturing steps of a method in accordance with a second embodiment of the present disclosure.

### DETAILED DESCRIPTION

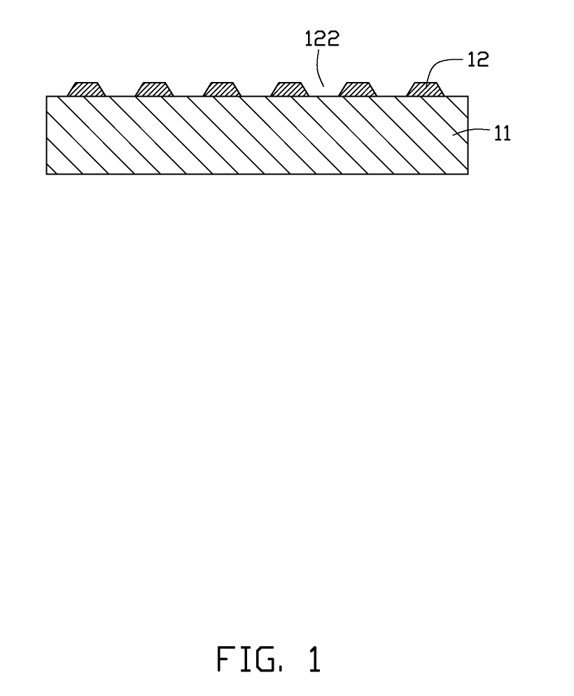

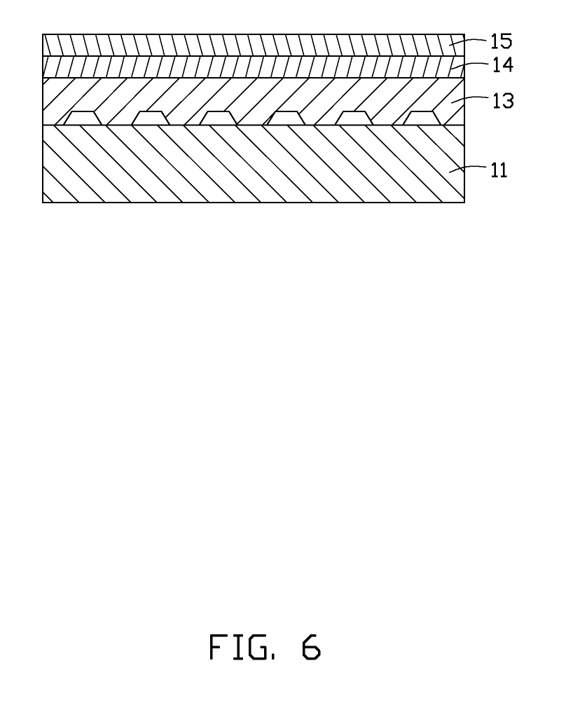

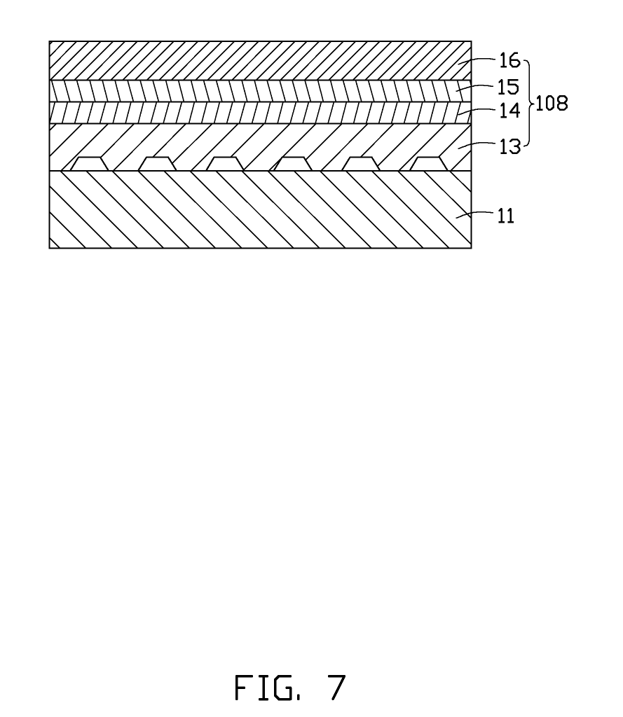

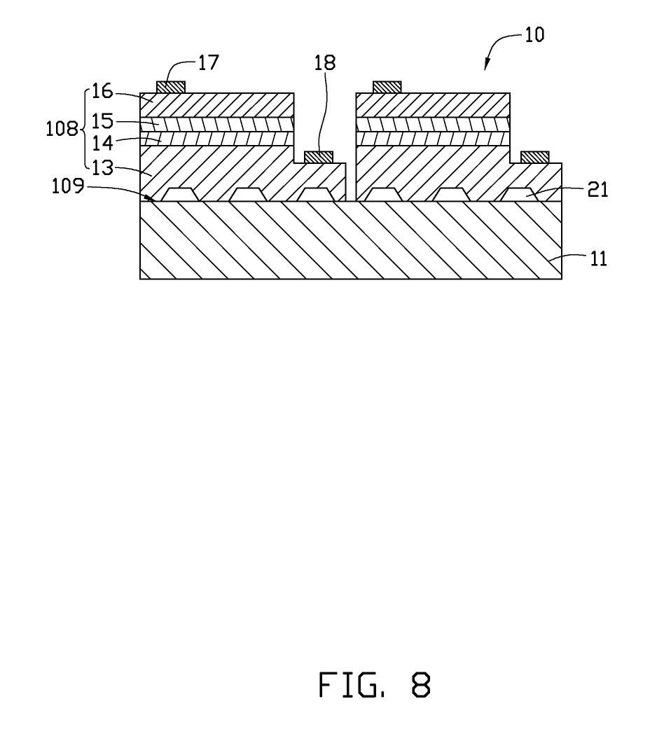

A first embodiment of a method for manufacturing a light emitting diode chip 10 (FIG. 8) is described in detail with reference to the FIGS. 1-8.

Referring to FIG. 1, a substrate 11 is provided and a patterned blocking layer 12 is formed on the substrate 11. The substrate 11 can be sapphire, silicon carbon, or silicon material. In the present embodiment, the sapphire is applied as the substrate 11. The patterned blocking layer 12 can be silicon dioxide (SiO₂) or silicon nitride (SiN) with grooves 122 therebetween. The grooves 122 may be continuous or partially continuous or with other shapes as a pattern. The continuous grooves 122 can be a grid among the patterned blocking layer 12 which consists of multiple cylinders or polygonal columns. The partially continuous grooves 122 can be parallel longitudinal grooves. Epitaxial region is defined on the top surface of the substrate 11 in the grooves 122.

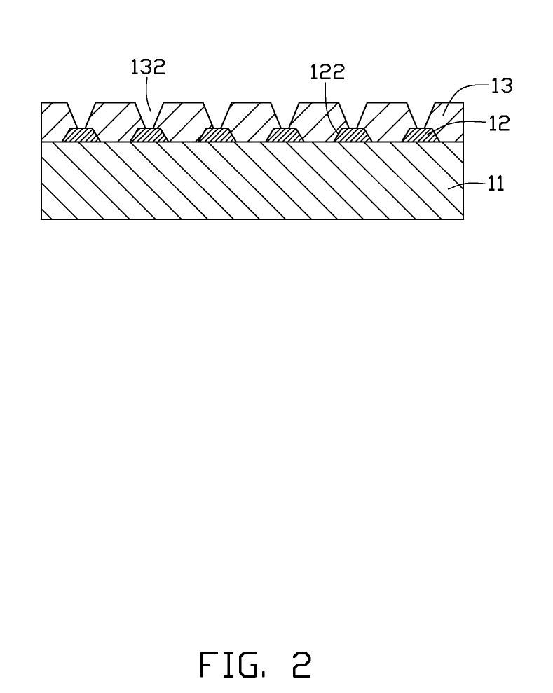

Referring to FIG. 2, an n-type semiconductor layer 13 is formed on the epitaxial region in the grooves 122 by Metal Organic Chemical Vapor Deposition (MOCVD) or Molecular Beam Epitaxy (MBE). The growth of the n-type semiconductor layer 13 is stopped before the n-type semiconductor layer 13 completely covers the patterned blocking layer 12. The n-type semiconductor layer 13 can be made of n-type GaN-based III-V semiconductor, such as n-AlₓIn_{y}Ga_{1-x-y}N. The grooves 122 are filled with the n-type semiconductor layer 13. An exposed space 132 is formed between two adjacent n-type semiconductor layers 13 and above a top of a corresponding part of the patterned blocking layer 12. A size of the space 132 is a matter of design according to the requirement of practical application.

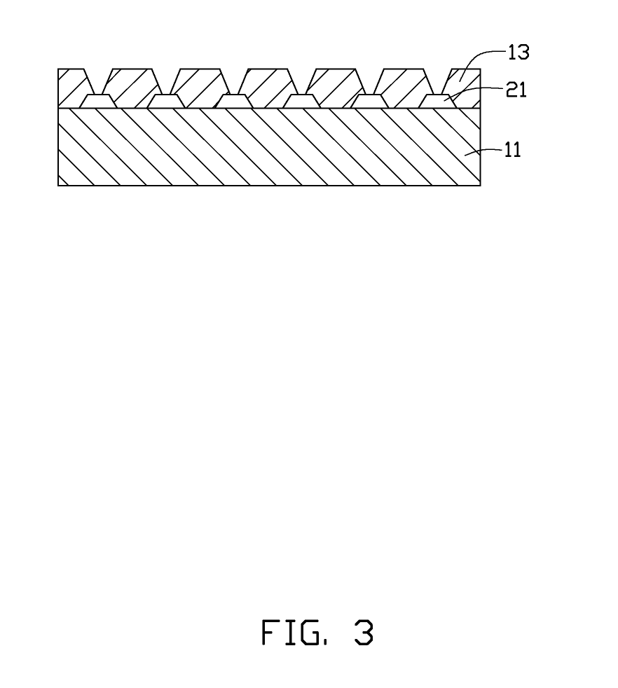

Referring to FIG. 3, then the patterned blocking layer 12 is removed by etching or other methods. For example, the patterned blocking layer 12 which is made of silicon dioxide (SiO₂) can be efficiently removed by Buffered Oxide Etch. The Buffered Oxide Etch may be a mixture of hydrofluoric acid and fluorin ammonium according to a predetermined ratio. After the patterned blocking layer 12 is removed, a number of holes 21 are defined at the position where the patterned blocking layer 12 is originally located. The profile of the holes is corresponding to that of the patterned blocking layer 12.

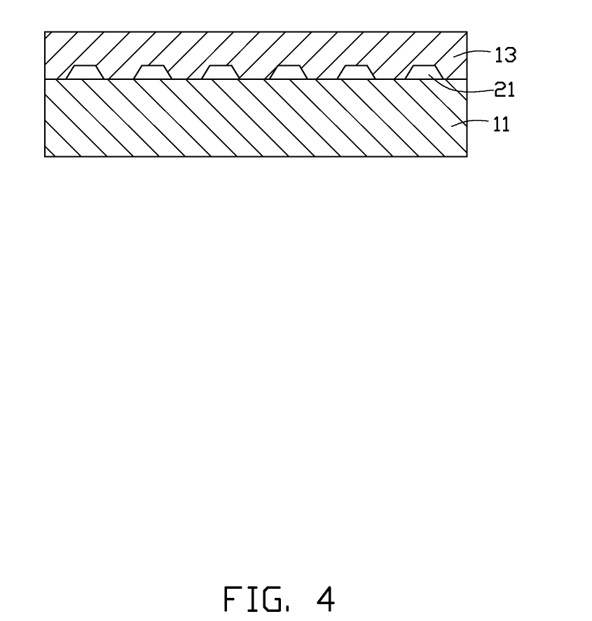

Referring to FIG. 4, the n-type semiconductor layer 13 is further grown by Metal Organic Chemical Vapor Deposition (MOCVD) or Molecular Beam Epitaxy (MBE). The newly formed parts of the n-type semiconductor layer 13 may be grown in the exposed space 132 above the holes 21 until the exposed spaces 132 are completely filled by the n-type semiconductor layer 13, whereby the holes 21 are completely surrounded between the substrate 11 and the n-type semiconductor layer 13.

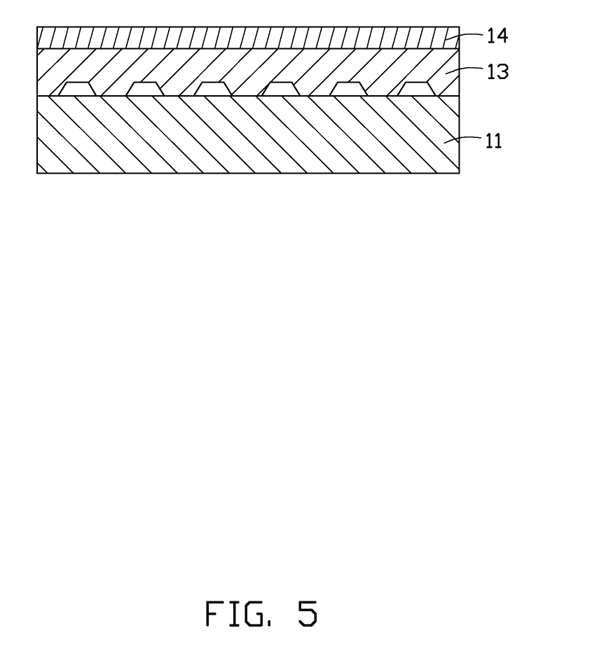

Referring to FIGS. 5-7, an active layer 14, a p-type current blocking layer 15, and a p-type contact layer 16 are then grown on the n-type semiconductor layer 13 in sequence. The n-type semiconductor layer 13, the active layer 14, the p-type current blocking layer 15, and the p-type contact layer 16 cooperatively form a light emitting structure 108. The p-type current blocking layer 15 and the p-type contact layer 16 may be a P-doped GaN, AlGaN, InGaN or AlInGaN layer, and the active layer 14 may be a multi-quantum well structure.

Referring to FIG. 8, then the light emitting structure 108 is etched downwardly from the p-type contact layer 16 until the n-type semiconductor layer 13 is exposed; thereafter, a first electrode 17 and a second electrode 18 are respectively formed on the p-type contact layer 16 and the exposed n-type semiconductor layer 13 by vacuum evaporation or sputtering deposition. Thus, the light emitting diode chip 10 has been formed. The first electrode 17 and the second electrode 18 may be made of one of Ti, Al, Ag, Ni, W, Cu, Pd, Cr and Au or an alloy thereof.

As shown in FIG. 8, the light emitting diode chip 10 includes the substrate 11 and the light emitting structure 108 formed on the substrate 11. The light emitting structure 108 includes the n-type semiconductor layer 13, the active layer 14, the p-type current blocking layer 15, the p-type contact layer 16 arranged one on the other in that order along a direction away from the substrate 11. The holes 21 are located at the connection between the substrate 11 and the n-type semiconductor layer 13. The holes 21 are distributed in a pattern, which are totally covered by the n-type semiconductor layer 13. The first electrode 17 and the second electrode 18 are respectively formed on the p-type contact layer 16 and the exposed n-type semiconductor layer 13.

During operation, the first electrode 17 and the second electrode 18 are electrically connected to a power source (not shown) to cause the active layer 14 to emit light. The holes 21 are configured for reflecting the light generated by the active layer 14 originally toward the substrate 11 to be away from the substrate 11; therefore, the luminescence efficiency of the light emitting diode chip 10 can be enhanced.

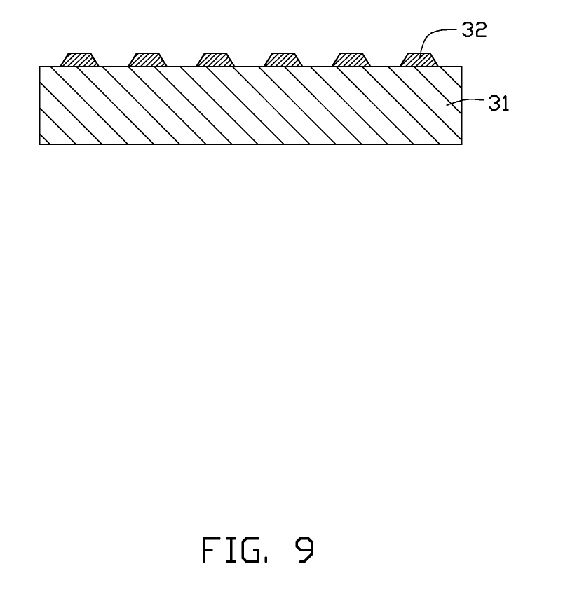

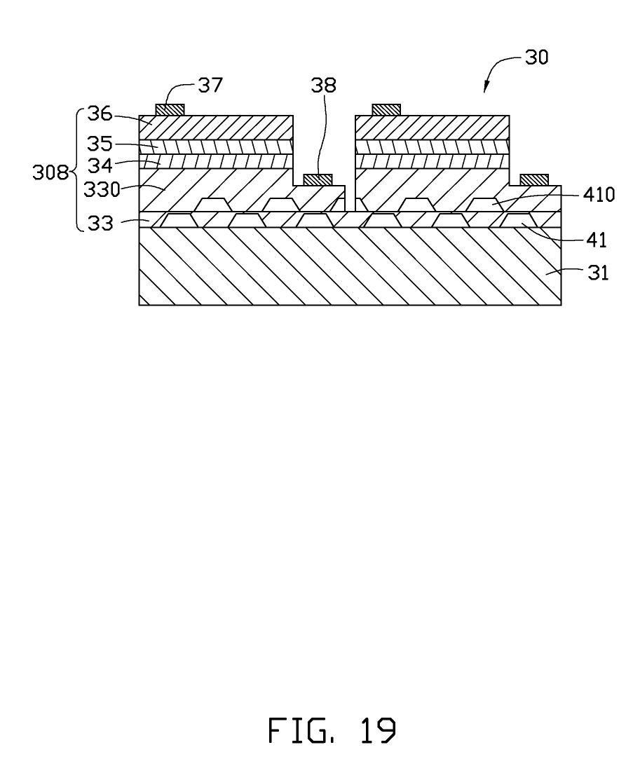

A second embodiment of a method for manufacturing a light emitting diode chip 30 (FIG. 19) is described in detail with reference to the FIGS. 9-19.

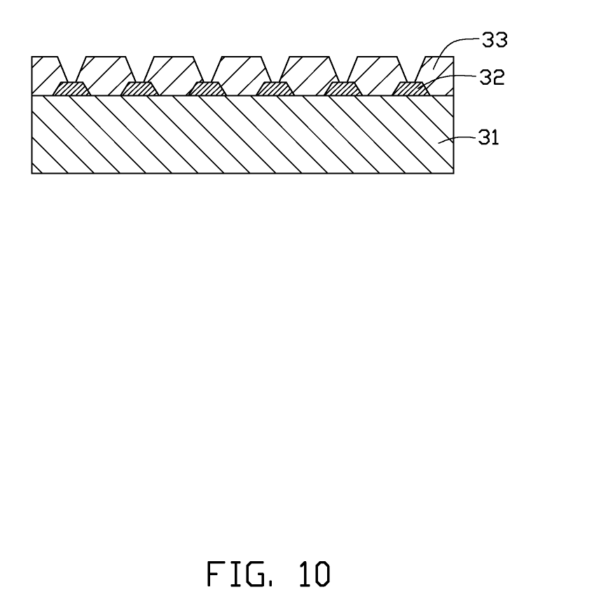

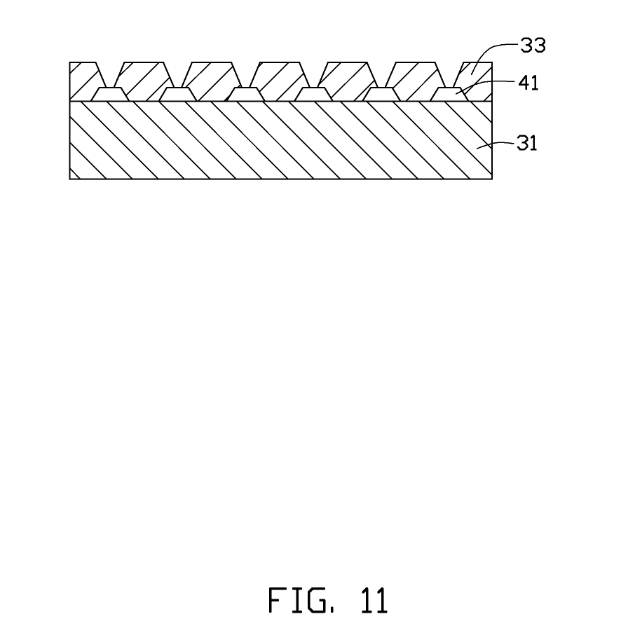

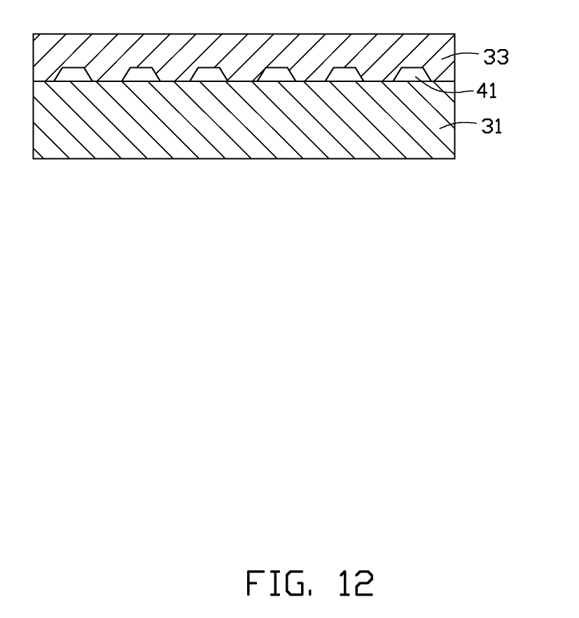

The method for manufacturing the light emitting diode chip 30 in accordance with the second embodiment is similar with the method in accordance with the first embodiment. Referring to FIG. 9, a substrate 31 is provided and a patterned blocking layer 32 is formed on the substrate 31. Referring to FIG. 10, an n-type semiconductor layer 33 is formed on the top face of the substrate 31 between each two adjacent parts of the patterned blocking layer 32 by MOCVD or MBE, and is stopped from growing before the n-type semiconductor layer 33 completely covers the patterned blocking layer 32. Referring to FIG. 11, the patterned blocking layer 32 is removed by Buffered Oxide Etch to form a number of holes 41 at the position where the patterned blocking layer 32 is originally exited, and the profile of the holes 41 is corresponding to that of the patterned blocking layer 32. Referring to FIG. 12, the n-type semiconductor layer 33 is further grown by MOCVD or MBE until the n-type semiconductor layer 33 becomes a continuous layer. The above steps of second embodiment are substantially same as those of the first embodiment.

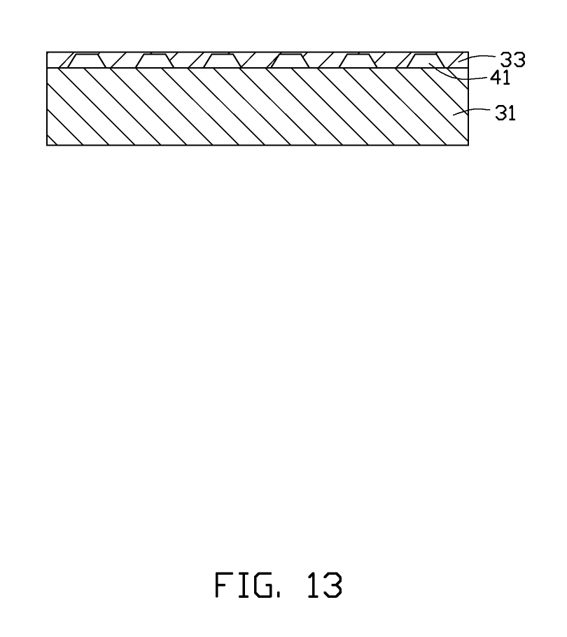

Referring to FIG. 13, a top portion of the n-type semiconductor layer 33 is removed by etching, with the holes 41 in the n-type semiconductor layer 33 intact. In this step, Inductively Coupled Plasma (ICP) technology for dry etching or plasma etching may be used to remove the top portion of the n-type semiconductor layer 33.

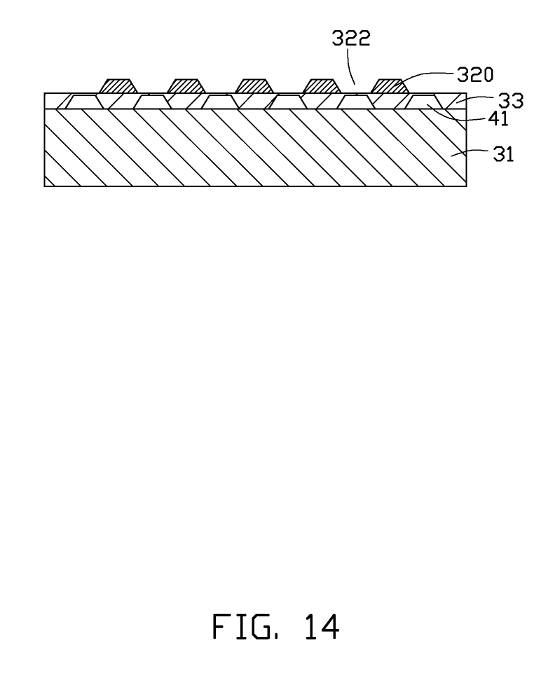

Referring to FIG. 14, a patterned blocking layer 320 is grown on the n-type semiconductor layer 33. The position of the patterned blocking layer 320 is different from that of the patterned blocking layer 32; that is, the patterned blocking layers 32, 320 can have different patterns/arrangements. In present embodiment, the patterned blocking layer 320 is offset from the holes 41, whereby all constituting parts of the patterned blocking layer 320 are alternate with the holes 41. A groove 322 is defined between each two adjacent parts of the patterned blocking layer 320.

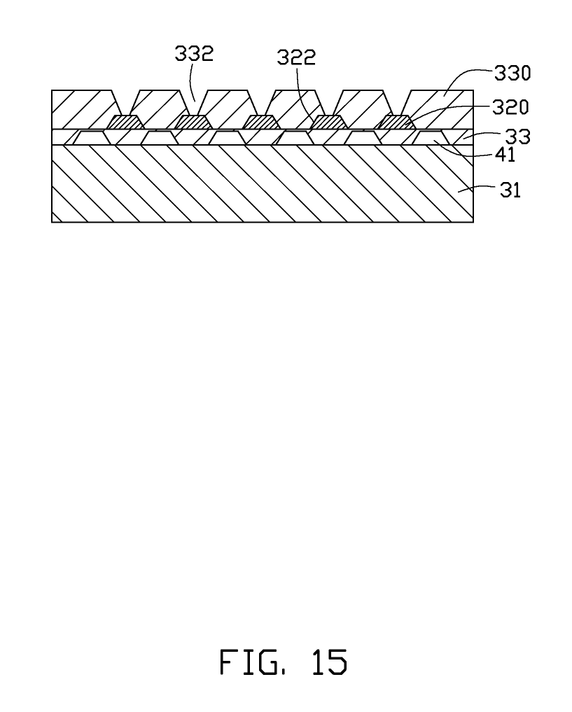

Referring to FIG. 15, an n-type semiconductor layer 330 is formed on the n-type semiconductor layer 33 and in the grooves 322 by MOCVD or MBE, and is stopped from growing before the n-type semiconductor layer 330 completely covers the patterned blocking layer 320, such that an exposed space 332 is defined above a top face of each part of the patterned blocking layer 32 between two adjacent parts of the n-type semiconductor layer 330. The n-type semiconductor layer 330 can be made of the n-type GaN-based III-V semiconductor, such as n-AlₓIn_{y}Ga_{1-x-y}N.

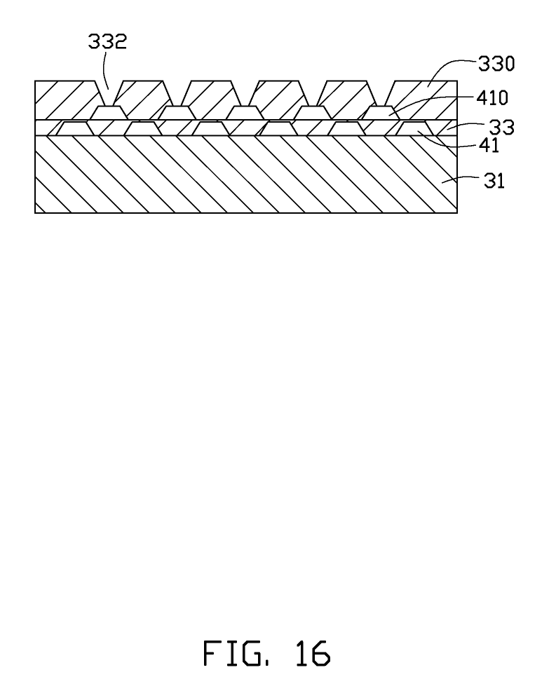

Referring to FIG. 16, the patterned blocking layer 320 is removed by etching or other methods. For example, the patterned blocking layer 320 which is made of silicon dioxide (SiO₂) can be efficiently removed by Buffered Oxide Etch. The Buffered Oxide Etch may be a mixture of hydrofluoric acid and fluorin ammonium according to a predetermined ratio. After the patterned blocking layer 320 is removed, a number of holes 410 are formed at the position where the patterned blocking layer 320 is originally existed. The profile of the holes 410 is corresponding to that of the patterned blocking layer 320.

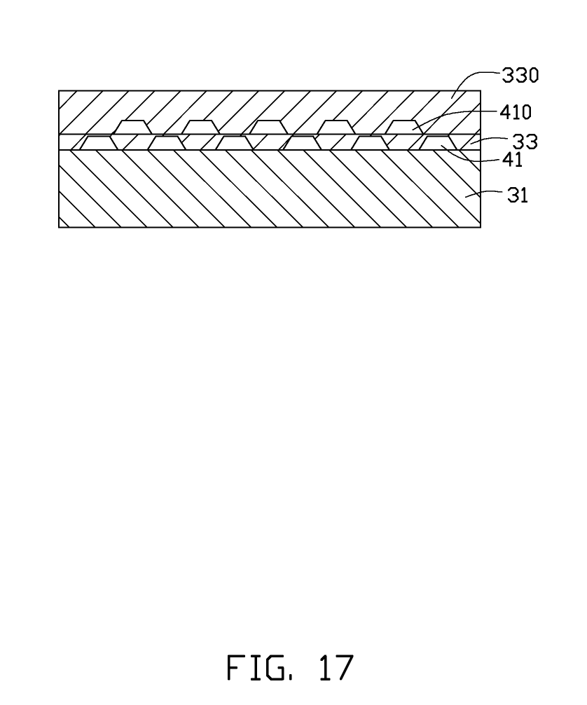

Referring to FIG. 17, the n-type semiconductor layer 330 is further grown on the n-type semiconductor layer 33 by Metal Organic Chemical Vapor Deposition (MOCVD) or Molecular Beam Epitaxy (MBE). The newly formed parts of the n-type semiconductor layer 330 is laterally grown to fill the exposed space 332 above each hole 410, whereby the holes 410 are surrounded between the n-type semiconductor layer 33 and the n-type semiconductor layer 330. Normally, the n-type semiconductor layer 33 and the n-type semiconductor layer 330 are made of the same material.

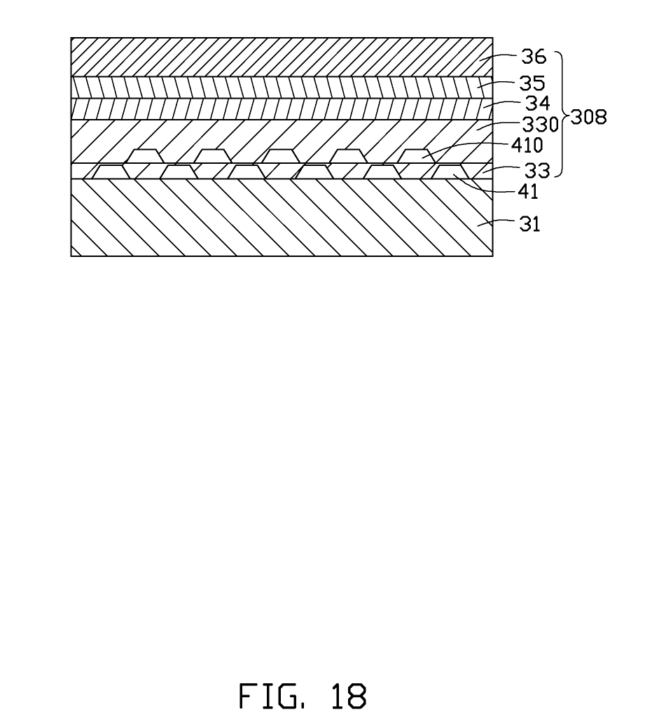

Referring to FIG. 18, an active layer 34 is grown on the n-type semiconductor layer 330, a p-type current blocking layer 35 is grown on the active layer 34, and a p-type contact layer 36 is grown on the p-type current blocking layer 35. The n-type semiconductor layer 33, 330, the active layer 34, the p-type current blocking layer 35, and the p-type contact layer 36 cooperatively form a light emitting structure 308. The p-type current blocking layer 35 and the p-type contact layer 36 may be a P-doped GaN, AlGaN, InGaN or AlInGaN layer, and the active layer 34 may be a multi-quantum well structure.

Referring to FIG. 19, the light emitting structure 308 is etched downwardly from the p-type contact layer 36 until the n-type semiconductor layer 330 is exposed; a first electrode 37 and a second electrode 38 are then respectively formed on the p-type contact layer 36 and the exposed n-type semiconductor layer 330 by vacuum evaporation or sputtering deposition. Thus, the light emitting diode chip 30 has been formed. The first electrode 37 and a second electrode 38 may be made of one of Ti, Al, Ag, Ni, W, Cu, Pd, Cr and Au or an alloy thereof.

As shown in FIG. 19, the light emitting diode chip 30 includes the substrate 31 and the light emitting structure 308 formed on the substrate 31. The light emitting structure 308 includes the n-type semiconductor layers 33, the n-type semiconductor layers 330, the active layer 34, the p-type current blocking layer 35, the p-type contact layer 36 arranged one on the other in that order along a direction away from the substrate 31. Actually, the n-type semiconductor layer 33 and the n-type semiconductor layer 330 are integrally inosculated with each other. The holes 41 are located at the connection between the substrate 31 and the n-type semiconductor layer 33, while the holes 410 are defined in the n-type semiconductor layer 330. The holes 41, 410 are distributed in a pattern and are totally covered by the n-type semiconductor layer 330. The patterned holes 41 are staggered from the holes 41. The first electrode 37 and the second electrode 38 are respectively formed on the p-type contact layer 36 and the exposed n-type semiconductor layer 330.

During operation, the first electrode 37 and the second electrode 38 are electrically connected to a power source (not shown) to cause the active layer 34 to emit light. The holes 410, 41 are configured for reflecting the light generated by the active layer 34 and originally toward the substrate 31 to be away from the substrate 31; therefore, the luminescence efficiency of the light emitting diode chip 30 can be enhanced.

Furthermore, since the staggered arrangement of the holes 41 and the holes 410, the light from the active layer 34 and downwardly toward the substrate 31 can be almost reflected upwardly; therefore, the luminescence efficiency of the light emitting diode chip 30 can be greatly improved.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for manufacturing a light emitting diode chip, comprising steps:
providing a substrate with a first patterned blocking layer formed thereon;
growing a first n-type semiconductor layer on the substrate between constituting parts of the first patterned blocking layer, the growing of the first n-type semiconductor layer being stopped before the first n-type semiconductor layer completely covers the first patterned blocking layer;
removing the first patterned blocking layer, whereby a plurality of first holes is formed at position where the first patterned blocking layer is originally existed;
continuing the growth of the first n-type semiconductor layer until the first holes are completely covered by the first n-type semiconductor layer; and
forming an active layer and a p-type current blocking layer on the first n-type semiconductor layer successively.

2. The method for manufacturing the light emitting diode chip of claim 1, further comprising following steps before forming the active layer and the p-type current blocking layer:
etching the first n-type semiconductor layer without exposing the first holes;
forming a second patterned blocking layer on the first n-type semiconductor layer;
growing a second n-type semiconductor layer on the first n-type semiconductor layer, and the growth of the second n-type semiconductor layer being stopped before the second n-type semiconductor layer completely covers the second patterned blocking layer;
removing the second patterned blocking layer, whereby a plurality of second holes is formed at position where the second patterned blocking layer is originally existed; and
continuing the growth of the second n-type semiconductor layer until the second holes are completely covered by the second n-type semiconductor layer.

3. The method for manufacturing the light emitting diode chip of claim 2, wherein the second patterned blocking layer and the first patterned blocking layer are offset from each other.

4. The method for manufacturing the light emitting diode chip of claim 2, wherein the second patterned blocking layer and the first patterned blocking layer have different patterns.

5. The method for manufacturing the light emitting diode chip of claim 1, wherein the first patterned blocking layer is made of one of silicon dioxide and silicon nitride.

6. The method for manufacturing the light emitting diode chip of claim 1, wherein the substrate is sapphire, silicon carbon, or silicon.

7. A light emitting diode chip, comprising a substrate and a light emitting structure, the light emitting structure comprising:
an n-type semiconductor layer, an active layer, a p-type current blocking layer and a p-type contact layer arranged one on the other in that order along a direction away from the substrate, a plurality of first holes located at the connection between the substrate and the n-type semiconductor layer, and the first holes being distributed in a pattern and are totally covered by the n-type semiconductor layer.

8. The light emitting diode chip of claim 7, wherein a plurality of second holes are formed in the n-type semiconductor layer above the first holes.

9. The light emitting diode chip of claim 8, wherein the second holes are distributed in a pattern, and the first holes are staggered from the second holes.
